(19) United States
(12) Patent Application Publication
(10) Pub. No.: US 2016/0029479 A1
(43) Pub. Date: Jan. 28, 2016

(54) ELECTROSTATIC DISCHARGE PROTECTION BOARD

(71) Applicant: SAMSUNG ELECTRO-MECHANICS CO., LTD., Suwon-Si (KR)

(72) Inventors: Jin O YOO, Suwon-si (KR); Keun Hoi KOO, Suwon-si (KR)

(73) Assignee: SAMSUNG ELECTRO-MECHANICS CO., LTD., Suwon-Si (KR)

(21) Appl. No.: 14/807,502

(22) Filed: Jul. 23, 2015

(30) Foreign Application Priority Data
Jul. 25, 2014 (KR) 10-2014-0094906
Apr. 27, 2015 (KR) 10-2015-0059026

(51) Int. Cl. H05K 1/02; H05K 1/11; H05K 1/09; H05K 1/03

(52) U.S. Cl. CPC H05K 1/0259; H05K 1/0306; H05K 1/115; H05K 1/0298; H05K 1/09; H05K 2201/0323; H05K 2201/0326; H05K 2201/0203; H05K 2201/0746

(57) ABSTRACT

An electrostatic discharge (ESD) protection board may include an electrostatic discharge (ESD) protection board, including a substrate, a pattern layer including circuit patterns formed on the substrate, and a high-voltage conductive material formed on the circuit patterns, which are insulated from each other, and a portion of the substrate between the circuit patterns.

### CROSS-REFERENCE TO RELATED APPLICATION

This application claims the benefit under 35 USC 119(a) of Korean Patent Application Nos. 10-2014-0094906 filed on Jul. 25, 2014 and 10-2015-0059026 filed on Apr, 27, 2015, in the Korean Intellectual Property Office, the entire disclosures of which are incorporated herein by reference.

### BACKGROUND

1. Field

The present disclosure relates to an electrostatic discharge (ESD) protection board.

2. Description of Related Art

Recently manufactured mobile terminals are produced with a capability to operate within a plurality of communications frequency bands through compliance with new communications standards and global roaming bands. Thus, antennas mounted in such mobile terminals are required to handle communications conducted within various communications frequencies.

A frequency band that has recently been used is 700 MHz to 2.7 GHz. However, because a single antenna does not have the capacity to undertake communications within all frequencies of such a wide frequency band, a plurality of electronic components are included to undertake communications within respective frequency bands are mounted in the mobile terminals.

Furthermore, as the integration of electronic components commonly provided in the mobile terminals has increased, there is an ongoing demand for the miniaturization and lightening of electronic components. However, because the electronic components that are miniaturized and lightened frequently have reduced tolerance to electrostatic discharge (ESD), an error rate of such electronic components has increased. An ESD protection element, such as a varistor or a diode, may be mounted on the signal lines of electronic components in order to increase tolerance to ESD. In this case, however, because a space in which such an ESD protection element is mounted may be reduced, while integration of the components of the mobile terminal is increased, ESD protection elements are difficult to implement when designing mobile terminals.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided an electrostatic discharge (ESD) protection board, including a substrate; a pattern layer including circuit patterns formed on the substrate; and a high-voltage conductive material formed on the circuit patterns, which are insulated from each other, and a portion of the substrate between the circuit patterns.

The high-voltage conductive material may include a piezo material including at least one of zinc oxide (ZnO) and silicon carbide (SiC).

The high-voltage conductive material may include a ceramic powder.

The high-voltage conductive material may be formed in a high temperature process.

The substrate may include a ceramic substrate.

The high-voltage conductive material may include a metal composite.

The high-voltage conductive material may be formed in a low temperature process.

The substrate may include a printed circuit board.

The high-voltage conductive material may include a binder containing conductive particles.

The conductive particles may include at least one of metal particles, carbon-based particles, and ceramic particles.

The metal particles may include at least one of nickel (Ni), aluminum (Al), and copper (Cu).

The carbon-based particles may include at least one of carbon black and graphite.

The ceramic particles may include at least one of zinc oxide (ZnO) and titanium dioxide (TiO₂).

One of the circuit patterns may maintain a ground voltage level.

The circuit patterns may include a first circuit pattern formed on one surface of the substrate, and a second circuit pattern formed on another surface of the substrate, wherein the first and the second circuit patterns are electrically connected by a via hole, which forms a signal transfer path between the first circuit pattern and the second circuit pattern.

The first circuit pattern, may include a signal input pattern, a terminal pattern, a ground pattern, and a wiring pattern configured to electrically connect the signal input pattern and the terminal pattern to each other, or electrically connect the ground pattern and the terminal pattern to each other.

The signal input pattern may be disposed at an end portion of the substrate.

A signal may be input to an electronic component mounted on the substrate through the signal input pattern, through the wiring pattern and the terminal pattern.

A voltage level of the ground pattern may be transferred to an electronic component mounted on the substrate, through the wiring pattern and the terminal pattern to form a bypass path for a peak high-voltage signal.

A terminal pattern may be electrically connected to an external connection terminal of the electronic component and to the ground pattern or the signal input pattern.

In response to a signal having a low voltage level being applied, the high-voltage conductive material may be a non-conductive material, and in response to a signal having a high-voltage level being applied, the high-voltage conductive material may be a conductive material.

In accordance with another illustrative example, there is provided an electrostatic discharge (ESD) protection board, including: a substrate including layers; a pattern layer including circuit patterns formed on at least one of the layers; and a high-voltage conductive material formed between the circuit patterns insulated from each other, wherein the high-voltage conductive material fills a via hole disposed in the substrate.

The via hole filled with the high-voltage conductive material may connect circuit patterns formed to be insulated from each other on one of the layers or on different layers.

Other features and aspects will be apparent from the following detailed description, the drawings, and the claims.

### BRIEF DESCRIPTION OF DRAWINGS

FIG. 1 is a perspective view of an electrostatic discharge (ESD) protection board, according to an embodiment; and

FIGS. 2 and 3 are cross-sectional views of a semiconductor module, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. These terms do not necessarily imply a specific order or arrangement of the elements, components, regions, layers and/or sections. Thus, a first element, component, region, layer or section discussed below could be termed a second element, component, region, layer or section without departing from the teachings description of the present invention.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the drawings, the shapes and dimensions of elements may be exaggerated for clarity, and the same reference numerals will be used throughout to designate the same or like elements.

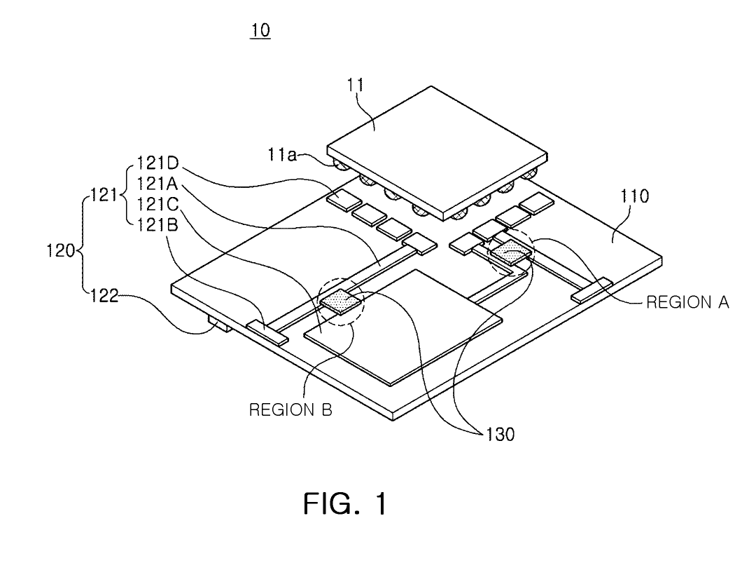

FIG. 1 is a perspective view of an electrostatic discharge (ESD) protection board 10, according to an embodiment.

As illustrated in FIG. 1, the ESD protection board 10 includes a substrate 110, a pattern layer 120 provided on the substrate 110, and a high-voltage conductive material 130.

The substrate 110 includes one of a printed circuit board and a ceramic substrate. In one illustrative example, the substrate includes all substrates on which a chip is mounted.

The substrate 110 is used as a main substrate in electronic products such as smartphones, wearable mobile devices, tablet PCs, PCs, and other electronic hardware products or devices, and package substrates mounted on the main substrates of such devices.

In one configuration, the substrate 110 is a single substrate in which an internal layer is not present. In an alternative embodiment, the substrate 110 is a multilayer substrate including one or more internal layers.

The pattern layer 120 is formed on the substrate 110. The pattern layer 120 includes a plurality of circuit patterns and are formed on a plurality of layers of the substrate 110, for instance, on internal layers thereof and on outer layers thereof, for example, uppermost and lowermost layers. The circuit patterns formed on the layers, respectively, are insulated from the circuit patterns formed on other layers, and some circuit patterns are insulated from other circuit patterns formed on the same layer. In an alternative configuration, the circuit patterns are formed on the substrate 110 as a single layer substrate, without an internal layer. In this alternative configuration, the circuit patterns are formed on the single layer substrate and are insulated from the circuit patterns formed on the same single layer substrate, and some circuit patterns are insulated from other circuit patterns formed on the same single layer substrate.

The pattern layer 120 is formed on one surface or on another surface of the substrate 110. Further, in a case in which the substrate 110 is a multilayer substrate, the pattern layer 120 is formed on at least one internal layer of the substrate 110.

Referring to FIG. 1, the pattern layer 120 includes a first circuit pattern 121 formed on one surface of the substrate 110, and includes a second circuit pattern 122 formed on the other surface of the substrate 110. The first and second circuit patterns 121 and 122 respectively include a plurality of circuit patterns which are insulated from each other.

The first and second circuit patterns 121 and 122, respectively formed on one surface and the other surface of the substrate 110, are electrically connected by a via hole. In an alternative embodiment, a plurality of via holes is formed between one surface and the other surface of the substrate 110. The circuit patterns connected to each other by the via hole maintain the same potential. Thus, the via hole forms a signal transfer path between the first circuit pattern 121 and the second circuit pattern 122.

At least one electronic component 11 is mounted on one surface of the substrate 110. At least one electronic component 11 mounted on the substrate 110 is electrically connected to the first circuit pattern 121 formed on one surface of the substrate 110 through an external connection terminal 11a. The electronic component 11 may include one of a saw duplexer and a saw filter.

Although FIG. 1 illustrates a case in which at least one electronic component 11 is mounted on one surface of the substrate 110, at least another electronic component 11 is embedded in the substrate 110 in addition to the at least one electronic component 11 being mounted on the one surface of the substrate 100, in a case in which the substrate 110 is implemented as a component embedded substrate. In this case, an embedded component embedded in the substrate 110 includes an integrated circuit (IC) and a passive element.

The at least one electronic component 11 mounted on the one surface of the substrate 110 is operated using a signal input to the substrate 110. The signal applied to the at least one electronic component 11 is input to the substrate 110 through a specific terminal.

The signal applied to the at least one electronic component 11 is input through one of the first circuit pattern 121 and the second circuit pattern 122 formed, mounted, embedded, positioned, or displaced on one surface and the other surface of the substrate 110, and is input through a circuit pattern formed on at least one internal layer of the substrate in the case in which the substrate 110 is a multilayer substrate. In a case in which the substrate 110 is a single layer substrate, the signal applied to the at least one electronic component 11 is input through one of the first circuit pattern 121 and the second circuit pattern 122 formed, mounted, embedded, positioned, or displaced on one surface and the other surface of the substrate 110.

Hereinafter, a description will be provided under an assumption that the signal applied to the electronic component 11 is input through the first circuit pattern 121 formed on one surface of the substrate 110.

The first circuit pattern 121 includes a wiring pattern 121A, a signal input pattern 121B, a ground pattern 121C, and a terminal pattern 121D.

The wiring pattern 121A electrically connects the signal input pattern 121B and the terminal pattern 121D to each other, or electrically connects the ground pattern 121C and the terminal pattern 121D to each other. In addition, although not specifically illustrated, the wiring pattern 121A may electrically connect the terminal patterns 121D to each other.

The signal input pattern 121B is disposed at an end portion of the substrate 110. The signal applied to the electronic component 11 is input to the signal input pattern 121B. The signal input to the signal input pattern 121B is transferred to the electronic component 11 which is mounted on the substrate 110, through the wiring pattern 121A and the terminal pattern 121D.

A voltage level of the ground pattern 121C is the same as a ground voltage level. The voltage level of the ground pattern 121C is transferred to the electronic component 11, which is mounted on the substrate 110, through the wiring pattern 121A and the terminal pattern 121D. The ground pattern 121C forms a bypass path for an unnecessary signal such as a peak high-voltage signal.

The terminal pattern 121D is electrically connected to the external connection terminal 11a of the electronic component 11 mounted on the substrate 110. The terminal pattern 121D is connected to the ground pattern 121C or the signal input pattern 121B.

As described above, the signal applied to the electronic component 11 is input to the signal input pattern 121B, wherein the above-mentioned signal may include an electrostatic discharge (ESD) component. In one example, a voltage level of the signal including the ESD component instantaneously and sharply increases or is maintained undesirably high. In a case in which the signal including the above-mentioned ESD component is transferred to the electronic component 11 mounted on the substrate 110, the electronic component 11 breaks or malfunctions.

Particularly, an element, such as the saw duplexer or the saw filter included in a mobile device, has tolerance against the peak high-voltage, lower than that of other elements. Therefore, when a voltage exceeding a blocking voltage is applied to the element, the element functions defectively.

According to an embodiment, the high-voltage conductive material 130 is disposed in the substrate 110, such that the malfunctioning of the electronic component 11 is prevented, even in a case in which the signal including the ESD component is received at the substrate 110.

The high-voltage conductive material 130 functions as a conductor when a voltage having the level of a reference voltage or above is applied thereto. For example, in a case in which a signal having a low voltage level is applied, the high-voltage conductive material 130 functions as a non-conductive material, but in a case in which a signal having a high-voltage level is applied, the high-voltage conductive material 130 functions as a conductive material.

In one example, the high-voltage conductive material 130 is a piezo material including at least one of zinc oxide (ZnO) and silicon carbide (SiC).

In addition, the high-voltage conductive material 130 may include a ceramic powder and may include a metal composite in addition thereto.

In a case in which the high-voltage conductive material 130 is formed of the metal composite, because the high-voltage conductive material 130 is formed using a low temperature process, the substrate 110 is also formed of a printed circuit board suitable for a low temperature process.

In addition, in a case in which the high-voltage conductive material 130 is formed of the ceramic powder, because the high-voltage conductive material 130 is formed using a high temperature process, the substrate 110 is also configured as the ceramic substrate suitable for the high temperature process.

In addition, the high-voltage conductive material 130 includes conductive particles and a binder containing the conductive particles. In this case, the high-voltage conductive material 130 is a paste in which the conductive particles and the binder are mixed.

The conductive particles include, but are not limited to, at least one of metal particles, carbon-based particles, and ceramic particles. In this case, the metal particles include, but are not limited to, at least one of nickel (Ni), aluminum (Al), and copper (Cu), the carbon-based particles include at least one of carbon black and graphite, and the ceramic particles include at least one of zinc oxide (ZnO) and titanium dioxide (TiO₂).

The binder includes at least one of epoxy, urethane, and silicone.

In one configuration, the high-voltage conductive material 130 is formed between the circuit patterns insulated from each other, among the plurality of circuit patterns. For instance, the high-voltage conductive material 130 is formed between the wiring patterns 121A, or may be formed between the wiring pattern 121A and the ground pattern 121C. Thus, even when a signal transmitted to and received at the substrate 110 through the singel input terminal includes an ESD component, malfunctioning of the electronic component 11 may be prevented.

Referring to FIG. 1, in one illustrative example, the high-voltage conductive material 130 is coated on a portion of the substrate between the wiring pattern 121A connected to the signal input pattern 121B and the wiring pattern 121A connected to the ground pattern 121C (region A). In addition, the high-voltage conductive material 130 is coated on a portion of the substrate between the wiring pattern 121A connected to the signal input pattern 121B and the ground pattern 121C (region B). In this case, the high-voltage conductive material 130 is coated using one of a screen printing method and a dispensing method.

According to an embodiment, the high-voltage conductive material 130 is disposed at an entrance part of the wiring pattern 121A connected to the signal input pattern 121B to effectively remove or cancel the ESD component in a signal received.

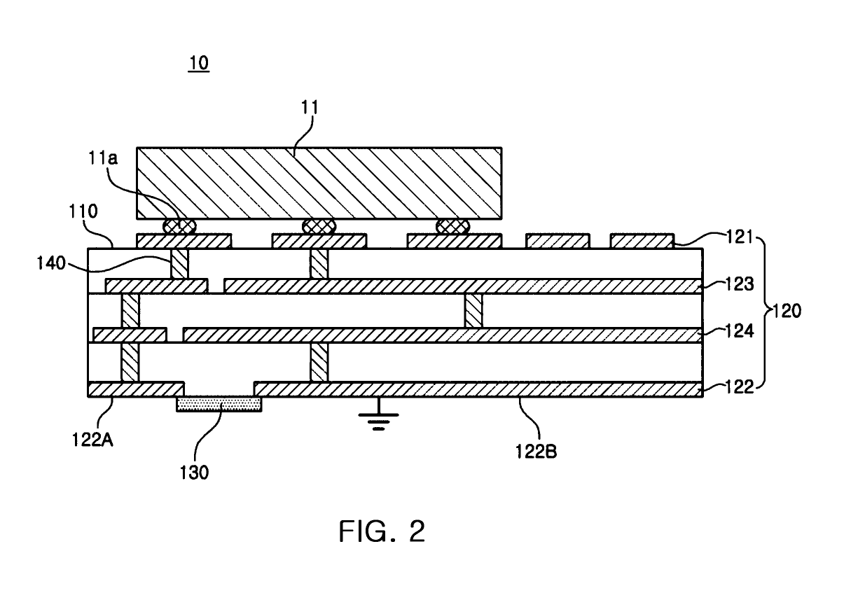

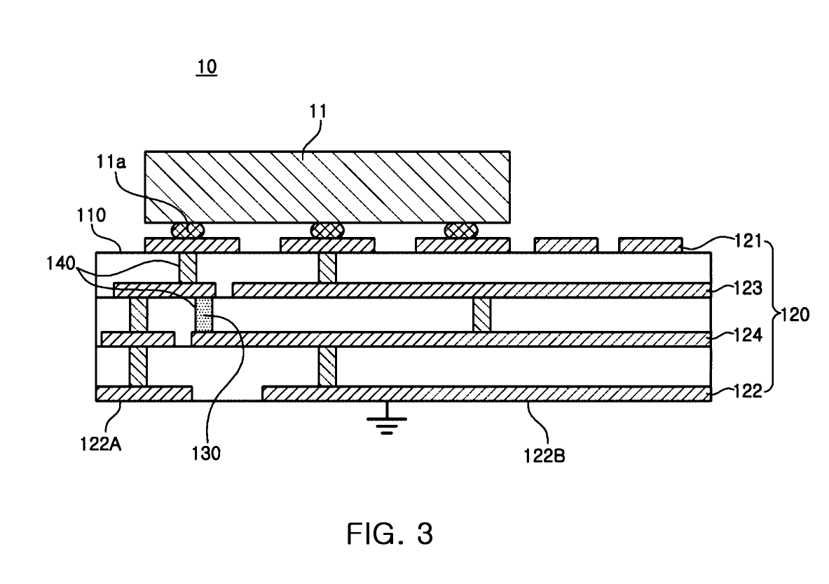

FIGS. 2 and 3 are cross-sectional views of the ESD protection board 10, according to an embodiment. The ESD protection board 10, according to embodiments illustrated in FIGS. 2 and 3, include the substrate 110, the pattern layer 120, the high-voltage conductive material 130, and a via 140.

Among the descriptions of the ESD protection board 10, according to the embodiments of FIGS. 2 and 3, the description the same as or similar to the description of the ESD protection board 10 according to the embodiment of FIG. 1 will be omitted, and a difference therebetween will mainly be described hereinafter.

The substrate 110 is a multilayer substrate configured to include a plurality of layers. Although FIGS. 2 and 3 illustrate a case in which the substrate 110 is configured with four layers, the substrate 110 may be a multilayer substrate including one or more internal layers, unlike those illustrated in FIGS. 2 and 3.

The pattern layer 120 is formed on the substrate 110. The pattern layer 120 includes a plurality of circuit patterns and is partly or entirely formed on a plurality of layers of the substrate 110, in detail, an internal layer thereof and an outer layer, for example, uppermost and lowermost layers thereof. The circuit patterns formed on the plurality of layers, respectively, may be insulated from the circuit patterns formed on different layers, and some of the circuit patterns formed on one layer may be insulated from each other.

The pattern layer 120 includes a first circuit pattern 121 formed on a first layer, which is the uppermost layer of the substrate 110. The pattern layer 120 also includes a second circuit pattern 122 formed on a fourth layer, which is the lowest layer of the substrate 110. The pattern layer 120 further includes a third circuit pattern 123 formed on a second layer, which is a lower layer of the first layer, and a fourth circuit pattern 124 formed on a third layer, which is a lower layer of the second layer.

The first to second circuit patterns 124 to 124 may respectively include a plurality of circuit pattern, which are insulated from each other.

The first to fourth circuit patterns 121 to 124 are electrically connected to the circuit patterns formed on layers which are adjacent to each other, through the via hole 140. A single via hole 140 or a plurality of via holes 140 are formed between the first to fourth layers. The circuit patterns connected to each other through the via hole 140 maintain the same potential. Thus, the via hole 140 forms a signal transfer path from a second circuit pattern 122 to the first circuit pattern 121.

At least one electronic component 11 is mounted on one surface of the substrate 110. At least one electronic component 11 mounted on the substrate is electrically connected to the first circuit pattern 121 formed on the uppermost layer of the substrate 110 through an external connection terminal 11a and 12a.

At least one electronic component 11 mounted on one surface of the substrate 110 is operated by a signal input to the substrate 110. The signal applied to the electronic component 11 is input to the substrate 110 through a specific terminal.

The signal applied to the electronic component 11 is input through one of the first to fourth circuit patterns 121 to 124 formed on the first to fourth layers of the substrate 110.

The embodiment of FIG. 1 provides a description in which the signal applied to the electronic component 11 is input through the first circuit pattern 121 of the substrate 110. In the embodiments of FIGS. 2 and 3, the signal applied to the electronic component 11 is input through the second circuit pattern 122 of the substrate 110.

The second circuit pattern 122 includes a signal input pattern 122A and a ground pattern 122B, insulated from each other. The signal input pattern 122A and the ground pattern 122B are respectively electrically connected to the first, third and fourth circuit patterns 121, 123, and 124, different from each other, through different via holes 140. A signal input to the signal input pattern 122A is transferred to one or more electronic components 11 through the via hole 140 and the first, third, and fourth circuit patterns 121, 123, and 124.

A voltage level of the ground pattern 122B may be the same as a ground voltage level. The ground pattern 122B forms a bypass path of an unnecessary signal such as a peak high-voltage.

A signal to operate the electronic component 11 is input to the signal input pattern 122A, wherein the above-mentioned signal may include an electrostatic discharge (ESD) component. A voltage level of the signal including the ESD component instantaneously and sharply increases or stays at an undesirably high level. In a case in which the above-mentioned ESD component is transferred to the electronic component 11 mounted on the substrate 110, the electronic component 11 breaks or malfunctions.

Particularly, a structural element, such as a saw duplexer or a saw filter, which may be included in a mobile device may have tolerance against the peak high-voltage lower than that of other structural elements. Therefore, when a voltage exceeding a blocking voltage is applied to the element, defects may be caused in the element.

According to an embodiment, the high-voltage conductive material 130 is disposed in the substrate 110, such that the malfunction of the electronic component 11 is prevented even in a case in which the signal including the ESD component is introduced to the substrate 110.

The high-voltage conductive material 130 is formed between the circuit patterns insulated from each other, among the plurality of circuit patterns.

The high-voltage conductive material 130 is formed between a plurality of circuit patterns insulated from each other on a layer. Referring to FIG. 2, the high-voltage conductive material 130 is coated on a portion of the substrate 110 between the circuit patterns of the second circuit pattern 122 that are insulated from each other, formed on the lowest layer of the substrate 110. In one embodiment, the high-voltage conductive material 130 is coated on a portion of the substrate between the signal input pattern 122A and the ground pattern 122B. In this case, the high-voltage conductive material 130 is coated using one of a screen printing method and a dispensing method.

The via hole 140 may be filled with the high-voltage conductive material 130. The via hole 140 filled with the high-voltage conductive material 130 does not electrically connect the respective layers, but may function as a conductive material only in a case in which a signal having a specific voltage level or more is applied thereto, according to characteristics of the high-voltage conductive material 130 as described above.

The via hole 140 filled with the high-voltage conductive material 130 is disposed between the circuit patterns, insulated or electrically separated from each other.

Referring to FIG. 3, the via hole 140 filled with the high-voltage conductive material 130 is formed between the circuit patterns insulated from each other in different layers. The via hole 140 filled with the high-voltage conductive material 130 connects the signal input pattern 122A to one circuit pattern of the fourth circuit pattern 124 connected to the ground pattern 122B.

In addition, although not illustrated, the via hole 140 filled with the high-voltage conductive material 130 is formed between the adjacent circuit patterns belonging to one layer. By way of example, the via hole 140 filled with the high-voltage conductive material 130 is formed to connect the circuit patterns, insulated from each other, of the fourth circuit pattern 124 formed on the third layer.

As set forth above, according to embodiments, the ESD components introduced to the board is effectively removed, whereby malfunction of the electronic components mounted on the board is prevented.

In addition, according to an embodiment, the ESD protection element is removed, whereby manufacturing costs are reduced and a mounting area of the components is increased.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An electrostatic discharge (ESD) protection board, comprising:
a substrate;
a pattern layer comprising circuit patterns formed on the substrate; and
a high-voltage conductive material formed on the circuit patterns, which are insulated from each other, and a portion of the substrate between the circuit patterns.

2. The ESD protection board of claim 1, wherein the high-voltage conductive material comprises a piezo material including at least one of zinc oxide (ZnO) and silicon carbide (SiC).

3. The ESD protection board of claim 1, wherein the high-voltage conductive material comprises a ceramic powder.

4. The ESD protection board of claim 3, wherein the high-voltage conductive material is formed in a high temperature process.

5. The ESD protection board of claim 4, wherein the substrate comprises a ceramic substrate.

6. The ESD protection board of claim 1, wherein the high-voltage conductive material comprises a metal composite.

7. The ESD protection board of claim 1, wherein the high-voltage conductive material is formed in a low temperature process.

8. The ESD protection board of claim 7, wherein the substrate comprises a printed circuit board.

9. The ESD protection board of claim 1, wherein the high-voltage conductive material comprises a binder containing conductive particles.

10. The ESD protection board of claim 9, wherein the conductive particles comprise at least one of metal particles, carbon-based particles, and ceramic particles.

11. The ESD protection board of claim 10, wherein the metal particles comprise at least one of nickel (Ni), aluminum (Al), and copper (Cu).

12. The ESD protection board of claim 10, wherein the carbon-based particles comprise at least one of carbon black and graphite.

13. The ESD protection board of claim 10, wherein the ceramic particles comprise at least one of zinc oxide (ZnO) and titanium dioxide (TiO₂).

14. The ESD protection board of claim 1, wherein one of the circuit patterns maintains a ground voltage level.

15. The ESD protection board of claim 1, wherein the circuit patterns comprise
a first circuit pattern formed on one surface of the substrate, and
a second circuit pattern formed on another surface of the substrate, wherein the first and the second circuit patterns are electrically connected by a via hole, which forms a signal transfer path between the first circuit pattern and the second circuit pattern.

16. The ESD protection board of claim 1, wherein the first circuit pattern, comprises:
a signal input pattern,
a terminal pattern,
a ground pattern, and
a wiring pattern configured to electrically connect the signal input pattern and the terminal pattern to each other, or electrically connect the ground pattern and the terminal pattern to each other.

17. The ESD protection board of claim 16, wherein the signal input pattern is disposed at an end portion of the substrate.

18. The ESD protection board of claim 16, wherein a signal is input to an electronic component mounted on the substrate through the signal input pattern, through the wiring pattern and the terminal pattern.

19. The ESD protection board of claim 16, wherein a voltage level of the ground pattern is transferred to an electronic component mounted on the substrate, through the wiring pattern and the terminal pattern to form a bypass path for a peak high-voltage signal.

20. The ESD protection board of claim 16, wherein a terminal pattern is electrically connected to an external connection terminal of the electronic component and to the ground pattern or the signal input pattern.

21. The ESD protection board of claim 1, wherein,
in response to a signal having a low voltage level being applied, the high-voltage conductive material is a non-conductive material, and
in response to a signal having a high-voltage level being applied, the high-voltage conductive material is a conductive material.

22. An electrostatic discharge (ESD) protection board, comprising:
a substrate comprising layers;
a pattern layer comprising circuit patterns formed on at least one of the layers; and
a high-voltage conductive material formed between the circuit patterns insulated from each other,
wherein the high-voltage conductive material fills a via hole disposed in the substrate.

23. The ESD protection board of claim 22, wherein the via hole filled with the high-voltage conductive material connects circuit patterns formed to be insulated from each other on one of the layers or on different layers.
